(19) United States
(12) Patent Application Publication
(10) Pub. No.: US 2026/0129753 A1
(43) Pub. Date: May 7, 2026

(54) PRINTED CIRCUIT BOARD

(71) Applicant: SAMSUNG ELECTRO-MECHANICS CO., LTD., Suwon-si (KR)

(72) Inventors: Chan Jin Park, Suwon-si (KR); Hyun Seok Yang, Suwon-si (KR); Myong Keun Jung, Suwon-si (KR); Eun Su Kwon, Suwon-si (KR)

(73) Assignee: SAMSUNG ELECTRO-MECHANICS CO., LTD., Suwon-si (KR)

(21) Appl. No.: 19/298,810

(22) Filed: Aug. 13, 2025

(30) Foreign Application Priority Data
Nov. 6, 2024 (KR) 10-2024-0155827

(51) Int. Cl. H05K 1/02

(52) U.S. Cl. CPC H05K 1/0296

(57) ABSTRACT

A printed circuit board includes a first insulating layer including a protrusion portion, and a metal layer disposed on the protrusion portion of the first insulating layer. A width of a lowermost portion of the protrusion portion is greater than a width of an uppermost portion of the protrusion portion.

### CROSS-REFERENCE TO RELATED APPLICATION(S)

This application claims benefit of priority to Korean Patent Application No. 10-2024-0155827 filed on Nov. 6, 2024 in the Korean Intellectual Property Office, the disclosure of which is incorporated herein by reference in its entirety.

### TECHNICAL FIELD

The present disclosure relates to a printed circuit board.

In response to the recent trend of miniaturization and weight reductions in mobile devices, there is an increasing need to achieve miniaturization and weight reduction in printed circuit boards (PCBs) mounted in such devices. As mobile devices have reduced weights and sizes, an undercut phenomenon may occur during the fabrication of microcircuits, which may lead to defects in the circuits. To meet such technical demands, research has been continuously conducted to improve the reliability of microcircuits while implementing circuits with reduced linewidths and distances therebetween.

### SUMMARY

An aspect of the present disclosure provides a printed circuit board including a fine metal layer having high reliability.

According to an aspect of the present disclosure, there is provided a printed circuit board including a first insulating layer including a protrusion portion, and a metal layer disposed on the protrusion portion of the first insulating layer. A width of a first end portion of the protrusion portion may be greater than a width of a second end portion of the protrusion portion.

A width of the protrusion portion may gradually increase from the second end portion to the first end portion.

A width of a first end portion of the metal layer may be greater than a width of a second end portion of the metal layer.

A width of the metal layer may gradually increase from a second end portion of the metal layer to a first end portion of the metal layer.

A width of a first end portion of the metal layer may be less than the width of the first end portion of the protrusion portion.

A width of a first end portion of the metal layer and the width of the second end portion of the protrusion portion may be equal to each other.

A side surface of the metal layer and a side surface of the protrusion portion may be coplanar with each other in at least a portion of a region in which the metal layer and the protrusion portion are connected to each other.

A width of the metal layer may gradually increase from a second end portion of the metal layer to a first end portion of the metal layer, and the width of the protrusion portion may gradually increase from the second end portion of the protrusion portion to the first end portion of the protrusion portion.

The metal layer may include a seed layer and a plating layer disposed on the seed layer.

A width of a first end portion of the seed layer may be greater than a width of a first end portion of the plating layer.

The seed layer may not extend to a region of the first insulating layer beyond the protrusion portion.

The first insulating layer may include a plurality of protrusion portions. A width of a first end portion of the metal layer may be greater than a distance between adjacent protrusion portions among the plurality of protrusion portions.

A width of a second end portion of the metal layer may be greater than the distance between the adjacent protrusion portions among the plurality of protrusion portions.

The width of the first end portion of the protrusion portion may be greater than the distance between the adjacent protrusion portions among the plurality of protrusion portions.

Widths of a second end portion and a first end portion of the metal layer may be equal to each other.

An end surface of a second end portion of the metal layer may include a curved surface.

An end surface of a second end portion of the metal layer may have a pointed shape.

The seed layer may include copper.

At least a portion of a side surface of the metal layer and at least a portion of a side surface of the protrusion portion may be inclined at the same angle with respect to a plane that is perpendicular to a direction in which the protrusion portion and the metal layer are stacked.

The curved surface may include an apex of the metal layer.

According to example embodiments of the present disclosure, a printed circuit board may include a fine metal layer having high reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view of an example of an electronic device;

FIG. 3 is a schematic cross-sectional view of an example of a printed circuit board;

FIG. 4 is a schematic plan view of a metal layer disposed on a protrusion portion of a first insulating layer;

FIG. 5 is a schematic cross-sectional view of another example of a printed circuit board;

FIG. 6 is a schematic cross-sectional view of another example of a printed circuit board;

FIG. 7 is a schematic cross-sectional view of another example of a printed circuit board; and

FIGS. 8 to 10 illustrate examples of a method of manufacturing a printed circuit board.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

### Electronic Device

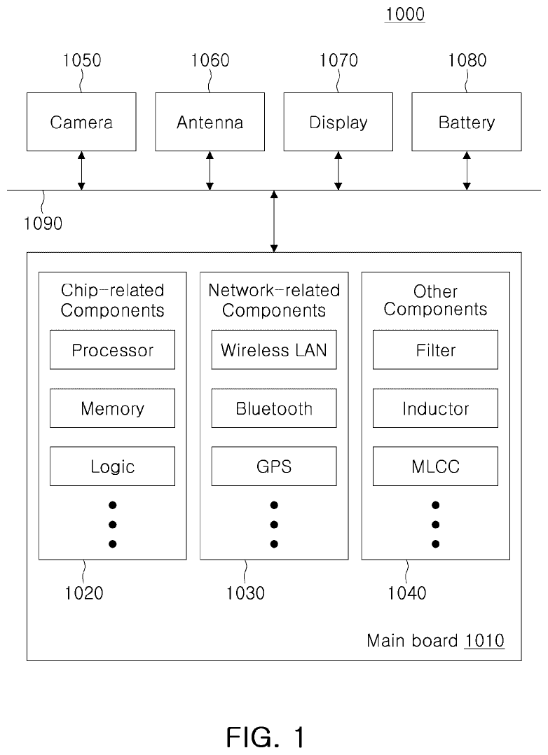

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

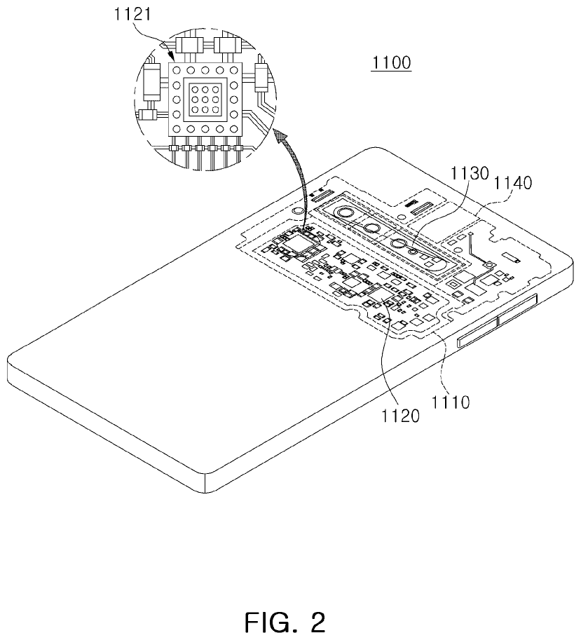

FIG. 2 is a schematic perspective view of an example of an electronic device.

Referring to the drawings, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not limited to the smartphone 1100, and may be other electronic devices, as described above.

### Printed Circuit Board

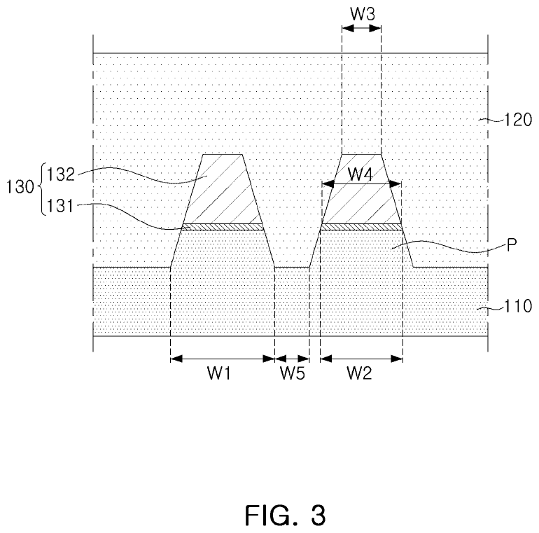

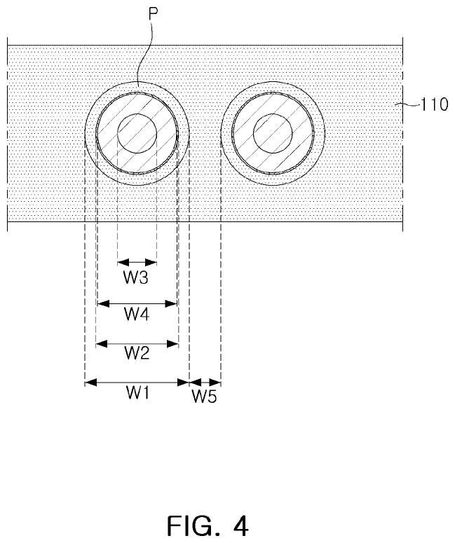

FIG. 3 is a schematic cross-sectional view of an example of a printed circuit board. FIG. 4 is a schematic plan view of a metal layer disposed on a protrusion portion of a first insulating layer. Referring to FIGS. 3 and 4, the printed circuit board according to the present example embodiment may include first and second insulating layers 110 and 120 and a metal layer 130. Here, the first insulating layer 110 may include a protrusion portion P. In addition, the metal layer 130 may be disposed on the protrusion portion P of the first insulating layer 110, and a width W1 of a lowermost portion (e.g., first end portion) of the protrusion portion P may be greater than a width W2 of an uppermost portion (e.g., second end portion) of the protrusion portion P. Such a shape of the protrusion portion P may be obtained through an anisotropic etching process to minimize an undercut of the metal layer 130, as described below. Hereinafter, main components of the printed circuit board will be described in detail.

The insulating layer 110 may include an insulating material. The insulating material may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may be a photosensitive material and/or a non-photosensitive material. For example, the insulating material may be an insulating material such as a solder resist (SR), an Ajinomoto build-up film (ABF), bismaleimide triazine (FR-4), prepreg (PPG), or resin-coated copper (RCC), an insulating material such as a copper lad laminate (CCL), or the like, but the present disclosure is not limited thereto, and other polymer materials may be used.

In the present example embodiment, the first insulating layer 110 may include the protrusion portion P. For example, the first insulating layer 110 may include a plurality of protrusion portions P formed on an upper surface thereof. As described above, the width W1 of the lowermost portion of the protrusion portion P may be implemented to be greater than the width W2 of the uppermost portion of the protrusion portion P. As a more specific example, a width of the protrusion portion P may gradually increase from the uppermost portion to the lowermost portion. Here, the widths W1 and W2 of the protrusion portion P may be widths measured in an arbitrary cross-section, and may be obtained by averaging values measured in a plurality of cross-sections spaced apart from each other at regular intervals. The above-described width measuring method may be applied to widths of other regions.

A second insulating layer 120 may be disposed on the first insulating layer 110, but may be excluded, as necessary. The second insulating layer 120 may include one material selected from a group of insulating materials the same as that of the first insulating layer 110, and may include an insulating material the same as that of the first insulating layer 110, but the present disclosure is not limited thereto. The second insulating layer 120 may be disposed on the first insulating layer 110 to bury the metal layer 130. A structure in which the metal layer 130 is buried in the second insulating layer 120, may mean that side and upper surfaces of the metal layer 130 are covered by the second insulating layer 120, while a lower surface of the metal layer 130 is not covered by the second insulating layer 120 but is exposed to a lower surface of the second insulating layer 120. In FIG. 3, it is illustrated that that the second insulating layer 120 is disposed on the first insulating layer 110, but the present disclosure is not limited thereto. A vertical arrangement in the drawings is set merely for convenience. Considering a printed circuit board in which the upper and lower portions in FIG. 3 are inverted, a structure of a printed circuit board according to an example may also be applied to a coreless structure manufactured using a carrier substrate.

The printed circuit board according to an example may further include an insulating layer and a metal layer disposed on a lower surface of the first insulating layer 110 and an upper surface of the second insulating layer 120, and may further include a via for interlayer connection of the metal layer, but the present disclosure is not limited thereto. In addition, the printed circuit board may further include general components of a printed circuit board such as other insulating layers, other circuit patterns, through-vias, and cavities, and may further include components that may be used by those skilled in the art.

The metal layer 130 may be disposed on the protrusion portion P of the first insulation layer 110. However, a portion of the metal layer 130 may also be present in a region of the first insulation layer 110 other than the protrusion portion P. The metal layer 130 may be formed on the protrusion portion P, and may have a shape similar to that of the protrusion portion P. Specifically, as illustrated in the drawings, a width W2 of a lowermost portion (e.g., first end portion) of the metal layer 130 may be greater than a width W3 of an uppermost portion (e.g., second end portion) of the metal layer 130. More specifically, a width of the metal layer 130 may gradually increase from the uppermost portion to the lowermost portion. In addition, the width W2 of the lowermost portion of the metal layer 130 may be less than the width W1 of the lowermost portion of the protrusion portion P. In addition, the width W2 of the lowermost portion of the metal layer 130 may be equal to the width W2 of the uppermost portion of the protrusion portion P. More specifically, a side surface of the metal layer 130 and a side surface of the protrusion portion P may be coplanar with each other in at least a portion of a region in which the metal layer 130 and the protrusion portion P are connected to each other. Accordingly, the widths of the metal layer 130 and the protrusion portion P may gradually increase from the uppermost portion of the metal layer 130 to the lowermost portion of the protrusion portion P.

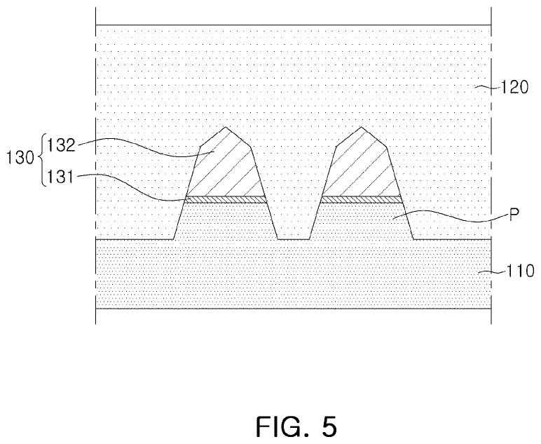

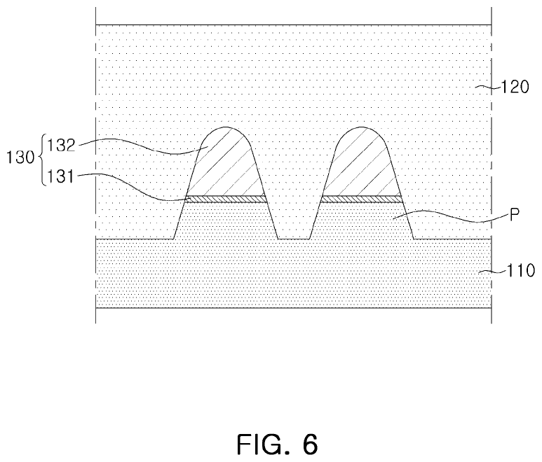

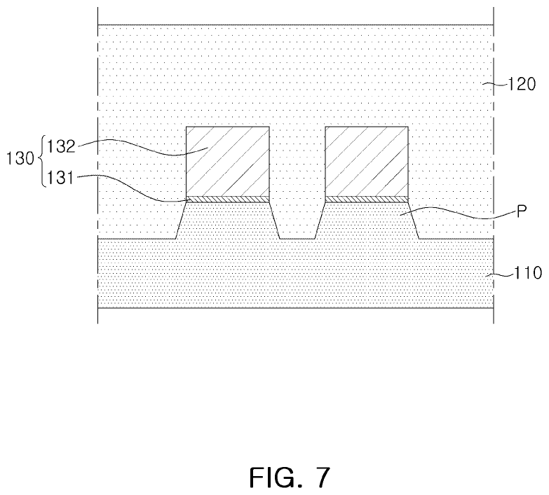

The above-described shapes of the metal layer 130 and the protrusion portion P may be obtained through an anisotropic etching process for removing the seed layer 131. In this case, as a portion of the first insulating layer 110 is removed, a remaining region, not removed, may be the protrusion portion P. In this case, in the example embodiment of FIG. 3, an upper surface (e.g., an end surface of a second end portion) of the metal layer 130 may have a flat shape. However, as in the modifications of FIGS. 5 and 6, the upper surface of the metal layer 130 may not have a flat shape. Specifically, FIG. 5 illustrates an example in which the upper surface of the metal layer 130 has a pointed shape, and FIG. 6 illustrates an example in which the upper surface of the metal layer 130 has a curved surface. The above-described modified shapes of the upper surface of the metal layer 130 may be obtained by adjusting an etching process to be described below. In addition, the metal layer 130 may not have the shape illustrated in FIG. 3, and the width of the metal layer 130 may not be substantially changed. That is, as in the modification of FIG. 7, the widths of the uppermost portion and the lowermost portion of the metal layer 130 may be equal to each other.

The metal layer 130 may include a seed layer 131 and a plating layer 132 disposed on the seed layer 131. In this case, the seed layer 131 may be in contact with the protrusion portion P. The seed layer 131 may be a seed for forming the plating layer 132. Considering the above-described function, the seed layer 131 may include copper (Cu), and may include aluminum (Al), silver (Ag), tin (Sn), gold (Au), nickel (Ni), lead (Pb), titanium (Ti), and/or alloys thereof. As will be described below in relation to a process, the seed layer 131 may initially be widely formed on the first insulating layer 110 and subsequently patterned by partial removal. In the present example embodiment, an undercut of the metal layer 130 may be minimized in the above-described process. Accordingly, the protrusion portion P and the metal layer 130 of the first insulating layer 110 having the above-described shapes may be obtained. In this case, a width W2 of a lowermost portion of the seed layer 131 may be greater than a width W4 of a lowermost portion of the plating layer 132. In addition, as a portion of the seed layer 131 is removed to form the metal layer 130 corresponding to a circuit pattern, the seed layer 131 may not extend to a region of the first insulating layer 110 beyond the protrusion portion P.

The plating layer 132 may be disposed on the seed layer 131. The plating layer 132 may include copper (Cu), aluminum (Al), silver (Ag), tin (Sn), gold (Au), nickel (Ni), lead (Pb), titanium (Ti), and/or an alloy thereof. The plating layer 132 may be a general circuit pattern, and may be formed with a plurality of patterns. The plurality of patterns may electrically transmit and receive signals to and from different patterns, or may exchange electrical signals with a metal layer further disposed on another layer. The plurality of patterns may be electrically short-circuited with other patterns to perform specific functions, or may perform various functions depending on the design, such as providing a mounting surface for components. The plating layer 132 may be formed through electrolytic plating or the like, using the seed layer 131 as a seed. Specifically, the plating layer 132 may be formed through a semi-additive process (SAP), a modified semi-additive process (MSAP), a tenting process, or a subtractive process, but the present disclosure is not limited thereto. Any known electrolytic plating process using the seed layer 131 for circuit pattern formation may be applied without limitation.

The seed layer 131 may function as a seed layer for plating the plating layer 132, and the plating layer 132 may function as a pattern or the like. Accordingly, a thickness of the plating layer 132 may be formed to be greater than a thickness of the seed layer 131. In this case, the thickness of the seed layer 131 and the thickness of the plating layer 132 may refer to vertical distances between upper surfaces and lower surfaces of the seed layer 131 and the plating layer 132, respectively. That is, the thickness of the seed layer 131 and the thickness of the plating layer 132 may refer to a thickness of a printed circuit board in a lamination direction.

The seed layer 131 and the plating layer 132 may include the same metal material, but the present disclosure is not limited thereto. The seed layer 131 and the plating layer 132 may include different metal materials. For example, each of the seed layer 131 and the plating layer 132 may be a metal layer including copper (Cu), but the present disclosure is not limited thereto. As another example, the seed layer 131 may include a material such as aluminum (Al), silver (Ag), tin (Sn), gold (Au), nickel (Ni), lead (Pb), titanium (Ti), and/or alloys thereof, and the plating layer 132 may include copper (Cu). That is, the seed layer 131 and the plating layer 132 may include different metal materials.

When the protrusion portion P and the metal layer 130 are formed in the above-described manner, an undercut of the metal layer 130 may be minimized, thereby miniaturizing the metal layer 130 and reducing a distance between the metal layers 130. Accordingly, the width W1 of the lowermost portion of the protrusion portion P may be greater than a distance W5 between adjacent protrusion portions P, among the plurality of protrusion portions P. In addition, the width W2 of the lowermost portion of the metal layer 130 may be greater than the distance W5 between the adjacent protrusion portions P, among the plurality of protrusion portions P. As a more limited example, the width W3 of the uppermost portion of the metal layer 130 may be greater than the distance W5 between the adjacent protrusion portions P, among the plurality of protrusion portions P.

An example of a method of manufacturing a printed circuit board will be described with reference to FIGS. 7 to 9. First, referring to FIG. 7, a seed layer 131 may be formed on a first insulating layer 110. The seed layer 131 may be formed through a known electroless plating process, but the present disclosure is not limited thereto. A material in which the seed layer 131 is formed may be prepared on the first insulating layer 110. The seed layer 131 may function as a seed for plating a plating layer 132 in an operation of forming the plating layer 132, an operation to be described below. Subsequently, a mask layer 200, for example, a dry film resist DFR, may be disposed on the seed layer 131. The mask layer 200 may be formed of a known dry film material, but the material is not limited to a dry film resist DFR. Any material capable of functioning as a plating resist may be used without limitation. After the mask layer 200 is disposed on the seed layer 131, a portion of a mask hole 120 may be patterned through exposure and development. In the operation of forming the plating layer 132, the operation to be described below, the mask layer 200 may function as a plating resist, and the plating layer 132 may be formed on a region of the seed layer in which the mask layer 200 is not formed.

Subsequently, the plating layer 132 may be formed on the seed layer 131. The plating layer 132 may be formed through an electroplating process or the like using the seed layer 131 as a seed. As described above, the plating layer 132 may be formed on a region of the seed layer 131 in which the mask layer 200 is not formed. Thereafter, the mask layer 200 may be removed. The mask layer 200 may be removed using a known method such as delamination or the like.

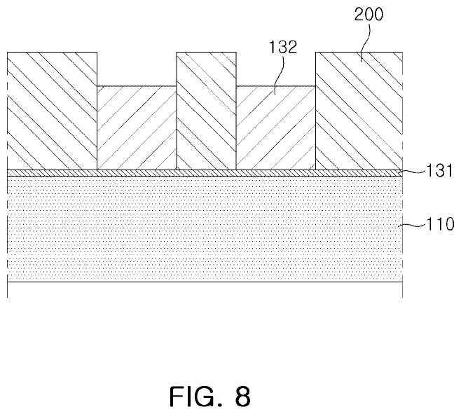

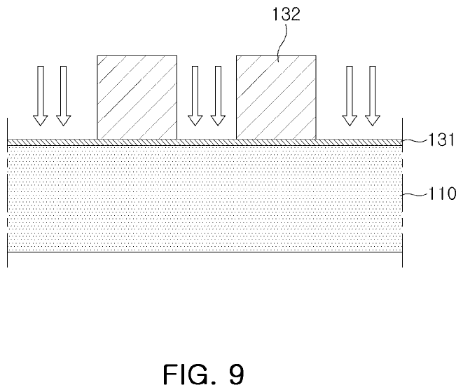

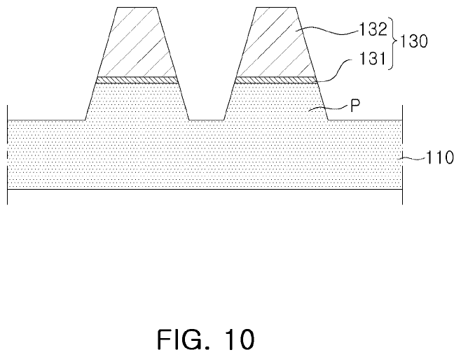

Referring to FIG. 8, a circuit pattern may be implemented by removing the seed layer 131, and the metal layer 130 and the first insulating layer 110 described above may be obtained therefrom. FIG. 9 illustrates a state after a process of the seed layer 131 is performed. In the process of the seed layer 131 process, an anisotropic etching process, for example, a dry etching process using plasma gas may be used. When the dry etching process is used, the seed layer 131, exposed without being covered by the plating layer 132, may be selectively removed, and an undercut of the metal layer 130 may be minimized, thereby miniaturizing the metal layer 130 and reducing a distance between the metal layers 130. In addition, when the dry etching process is used, a region of the first insulating layer 110, not covered by the plating layer 132, may be partially removed, and a protrusion portion P having a width gradually decreasing from a lower portion thereof to an upper portion thereof may be formed. In addition, the plating layer 132 may also have a width gradually decreasing from a lower portion thereof to an upper portion thereof.

Among other operations, operations that are the same as those in a method of manufacturing a printed circuit board according to an example or a method of manufacturing a printed circuit board according to another example may be applied to a printed circuit board according to another example, and thus a repeated description thereof will be omitted.

As used herein, the term “gradually increase” may be defined by a side surface of the protrusion portion P or a side surface the metal layer 130, and such side surface is inclined at an angle of 80° to 89.9° with respect to a plane (e.g., a horizontal plane) that is perpendicular to a direction in which the protrusion portion P and the metal layer are stacked 130.

The widths, distances, and angle described herein may be measured by an optical microscope or a scanning electron microscope. Other methods and/or tools appreciated by one of ordinary skill in the art, even if not described in the present disclosure, may also be used.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected. ” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first insulating layer including a protrusion portion; and
a metal layer disposed on the protrusion portion of the first insulating layer,
wherein a width of a first end portion of the protrusion portion is greater than a width of a second end portion of the protrusion portion.

2. The printed circuit board of claim 1, wherein a width of the protrusion portion gradually increases from the second end portion to the first end portion.

3. The printed circuit board of claim 1, wherein a width of a first end portion of the metal layer is greater than a width of a second end portion of the metal layer.

4. The printed circuit board of claim 1, wherein a width of the metal layer gradually increases from a second end portion of the metal layer to a first end portion of the metal layer.

5. The printed circuit board of claim 1, wherein a width of a first end portion of the metal layer is less than the width of the first end portion of the protrusion portion.

6. The printed circuit board of claim 1, wherein a width of a first end portion of the metal layer and the width of the second end portion of the protrusion portion are equal to each other.

7. The printed circuit board of claim 1, wherein a side surface of the metal layer and a side surface of the protrusion portion are coplanar with each other in at least a portion of a region in which the metal layer and the protrusion portion are connected to each other.

8. The printed circuit board of claim 7, wherein a width of the metal layer gradually increases from a second end portion of the metal layer to a first end portion of the metal layer, and the width of the protrusion portion gradually increases from the second end portion of the protrusion portion to the first end portion of the protrusion portion.

9. The printed circuit board of claim 1, wherein the metal layer includes a seed layer and a plating layer disposed on the seed layer.

10. The printed circuit board of claim 9, wherein a width of a first end portion of the seed layer is greater than a width of a first end portion of the plating layer.

11. The printed circuit board of claim 9, wherein the seed layer does not extend to a region of the first insulating layer beyond the protrusion portion.

12. The printed circuit board of claim 1, wherein
the first insulating layer includes a plurality of protrusion portions, and
a width of a first end portion of the metal layer is greater than a distance between adjacent protrusion portions among the plurality of protrusion portions.

13. The printed circuit board of claim 12, wherein a width of a second end portion of the metal layer is greater than the distance between the adjacent protrusion portions among the plurality of protrusion portions.

14. The printed circuit board of claim 12, wherein the width of the first end portion of the protrusion portion is greater than the distance between the adjacent protrusion portions among the plurality of protrusion portions.

15. The printed circuit board of claim 1, wherein widths of a second end portion and a first end portion of the metal layer are equal to each other.

16. The printed circuit board of claim 1, wherein an end surface of a second end portion of the metal layer includes a curved surface.

17. The printed circuit board of claim 1, wherein an end surface of a second end portion of the metal layer has a pointed shape.

18. The printed circuit board of claim 9, wherein the seed layer includes copper.

19. The printed circuit board of claim 1, wherein at least a portion of a side surface of the metal layer and at least a portion of a side surface of the protrusion portion are inclined at the same angle with respect to a plane that is perpendicular to a direction in which the protrusion portion and the metal layer are stacked.

20. The printed circuit board of claim 16, wherein the curved surface includes an apex of the metal layer.
